(19) United States
(12) Patent Application Publication
(10) Pub. No.: US 2005/0067720 A1
(43) Pub. Date: Mar. 31, 2005

(54) Method of forming an encapsulation layer on a back side of a wafer

(75) Inventors: Yu-Pen Tsai, Kaohsiung City (TW); Chih-Chiang Liu, Kaohsiung City (TW); Wei-Min Hsiao, Kaohsiung City (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaoshiung (TW)

(21) Appl. No.: 10/949,212

(22) Filed: Sep. 27, 2004

(30) Foreign Application Priority Data
Sep. 26, 2003 (TW) 092126692

(51) Int. Cl. H01L 21/00; H01L 21/44

(52) U.S. Cl. 257/787; 438/127

(57) ABSTRACT

A manufacturing method of forming an encapsulation layer on a back surface of a wafer mainly comprises the following steps. Firstly, there is provided a wafer having an active surface and a back surface, wherein the active surface has a plurality of bumps formed thereon. Next, an encapsulation is provided on the back surface of the wafer and a mold is provided to have a mold surface of the mold disposed over the back surface. Afterwards, the mold surface is heated and moved to press the encapsulation simultaneously so as to have the encapsulation entirely distributed over the back surface of the wafer to form the encapsulation layer, with a flat surface, covering the back surface of the wafer.

### BACKGROUND OF THE INVENTION

1. Field of Invention

This invention relates to a manufacturing method of forming a wafer level package. More particularly, the present invention is related to a manufacturing method of forming an encapsulation layer on a back side of a wafer.

2. Related Art

In this information explosion age, integrated circuits products are used almost everywhere in our daily life. As fabricating technique continue to improve, electronic products having powerful functions, personalized performance and a higher degree of complexity are produced. Nowadays, most electronic products are relatively light and have a compact body. Hence, in semiconductor production, various types of high-density semiconductor packages have been developed. Flip chip is one of the most commonly used techniques for forming an integrated circuits package. Moreover, compared with a wire-bonding package or a tape automated bonding (TAB) package, a flip-chip package uses a shorter electrical path on average and has a better overall electrical performance. In a flip-chip package, the bonding pads on a chip and the contacts on a substrate are connected together through a plurality of bumps formed on the chip by a conventional bumping process and then an underfill material is filled into the gap between the chip and the substrate to encapsulate the bumps so as to well protect the bumps. In such a manner, the reliability of such flip chip package is enhanced.

As mentioned above, in a conventional flip chip process, the chip is attached to a substrate by mounting the bumps of the chip onto the bonding pads of a substrate. Usually, there are a plurality of bumps formed on the active surface of the wafer before the wafer is singulated into a plurality of chips. However, after the bumps are formed, the back surface of the wafer is directly exposed to the outside without any protection layers formed thereon. Accordingly, a new technology, a compound applied on a back side of a wafer, is applied to well protect the wafer from being damaged.

As disclosed in U.S. Pat. No. 6,022,758, there is a wafer level package is provided. Therein, there are insulation layers formed on the active surface and back surface simultaneously and respectively, and apertures formed in the insulation layers for forming bumps therein. However, such conventional technology doesn't disclose the method of forming encapsulation layer on the back surface of the wafer and can't apply to form an encapsulation layer on the back surface of the wafer after the bumps are formed on the active surface of the wafer. To be apprehensible, if the encapsulation layer is formed by the method of attaching a tape to the back surface of the wafer, it is easy to form bubbles and voids between the tape and the back surface due to the tape not well attached to the back surface of the wafer. Consequently, well-known methods, spin-coating and screen printing, of forming an encapsulation layer on the back surface of the wafer are provided and performed. However, no matter the spin-coating and screen-printing methods are, the flatness of the encapsulation layer is not good after the encapsulation layer is cured and hardened. Accordingly, there is needed a grinding step to smooth the surface of the encapsulation layer. In addition, the curing process can not be performed right away after the encapsulation layer is disposed on the back surface of the wafer so as to cause the process flow to be complex.

Furthermore, another wafer level packaging process disclosed in TW Pub. 483138 is disclosed. Therein, a step of dispensing an epoxy resin on the back surface of the wafer is performed. However, the curing process can not be performed right away and usually there are voids formed therein. Accordingly, not only the process becomes more complex but also the reliability of the package is not good.

Therefore, providing another manufacturing method to solve the mentioned-above disadvantages is the most important task in this invention.

### SUMMARY OF THE INVENTION

In view of the above-mentioned problems, this invention is to provide a manufacturing method of forming an encapsulation layer on a back surface of a wafer so as not only to form a flat protection layer on the back surface of the wafer more quickly but also simplify the process flow by eliminating the step of smoothing the protecting layer.

To achieve these and other advantages and in accordance with the purpose of the invention, as embodied and broadly described herein, the invention specifically provides a manufacturing method of forming an encapsulation layer on a back surface of a wafer. The manufacturing method mainly comprises providing a wafer having an active surface and a back surface, disposing an encapsulation on the back surface, providing a mold having a mold surface disposed over the encapsulation, moving the mold surface to press the encapsulation and heating the mold simultaneously so as to have the encapsulation distributed entirely over the back surface of the wafer. Thus, encapsulation layer with a flat surface on the back surface of the wafer is formed. Optionally, the wafer may have a plurality of bumps formed on the active surface of the wafer and a passivation or protection layer, named as polymer collars, encompassing the bumps to well protect the bumps from being damaged.

It is to be understood that both the foregoing general description and the following detailed description are exemplary, and are intended to provide farther explanation of the invention as claimed.

### BRIEF DESCRIPTION OF THE DRAWINGS

The invention will become more fully understood from the detailed description given herein below illustrations only, and thus are not limitative of the present invention, and wherein:

FIG. 1 is a flow chart illustrating the process flow of a manufacturing method of forming an encapsulation layer on a back surface of a wafer according to the preferred embodiment of this invention; and

FIGS. 2 to 8 are partially enlarged cross-sectional views showing the progression of steps for forming an encapsulation layer on a back surface of a wafer according to the preferred embodiment of this invention.

### DETAILED DESCRIPTION OF THE INVENTION

The manufacturing method thereof according to the preferred embodiment of this invention will be described herein below with reference to the accompanying drawings, wherein the same reference numbers are used in the drawings and the description to refer to the same or like parts.

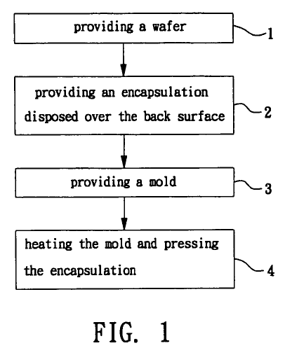

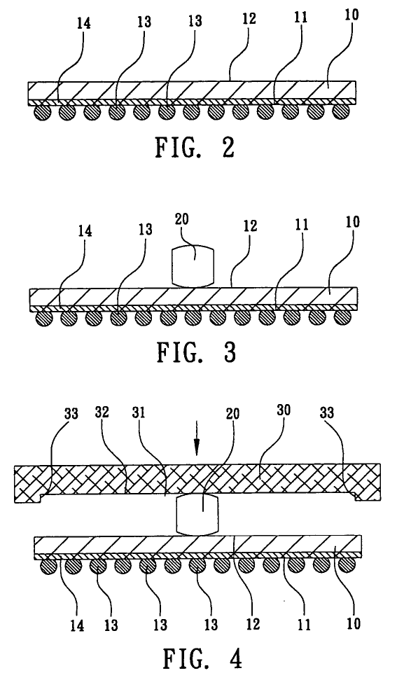

As shown in FIG. 1, it illustrates a process flow of a manufacturing method of forming an encapsulation layer on a back surface of a wafer. The manufacturing method mainly comprises the following steps of providing a wafer as shown in step 1, disposing an encapsulation on a back surface of the wafer as shown in step 2, providing a mold with a mold surface disposed over the encapsulation and back surface of the wafer as shown in step 3, and heating the mold and simultaneously moving the mold surface to contact and press the encapsulation so as to have the encapsulation distributed entirely over the back surface of the wafer to form the encapsulation layer as shown in step 4. Referring to FIG. 2, it illustrates the step 1. Therein, the wafer 10 has an active surface 11 and a back surface 12, wherein the active surface 11 has a plurality of bumps 13 formed thereon. To be noted, the bumps 13 can be formed of materials selected from gold, tin-lead alloy, copper, and conductive polymer. Therein, the bumps 13 are reflowed to be securely attached to the wafer 10. Furthermore, there is a stress buffer layer, stress release layer or a protection layer, usually named as polymer collars, formed on the active surface to encompass the bumps 13 as mentioned below. Optionally, there is further a wafer thing process before all the steps are performed. In other words, the wafer 10 may be performed a grinding process, grinding the back surface 12 of the wafer 10, to thin the wafer 10.

Referring to FIG. 3, it illustrates the step 2 of providing an encapsulation 20, a thermosetting compound or thermosetting pellet, disposed over the back surface 12 of the wafer 10. Therein, the encapsulation is a pre-formed body with a predetermined size and comprising resin, filler, hardener, Carnaub Wax and Ester Wax therein.

Next, Referring to FIG. 4, it illustrates the step 3 of providing a mold having a mold surface disposed over the back surface 12 of the wafer 10. In this embodiment, the mold 30 has a mold chase 31 having a flat mold surface 32 and a mold wall 33. Therein, the mold surface 32 is utilized to contact, press and smooth the encapsulation 20 and transfer the heat from the mold 30 to encapsulation 20, and the mold wall 33 is restricted the flow of the encapsulation within the mold chase 31 when the encapsulation 20 is melted and transferred into a liquid body.

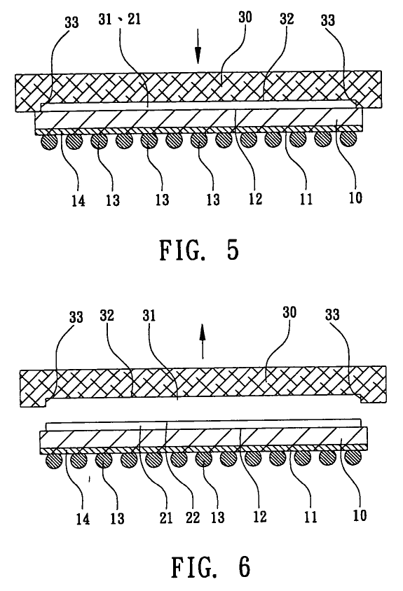

Afterwards, referring to FIG. 4 again and FIG. 5, it illustrates the step 4 of moving the mold surface 32 to press the encapsulation 20 and cause the encapsulation enclosed within the mold chase 31 and simultaneously heating the mold 30 to melt the encapsulation 20 to form an encapsulation layer 21 to entirely cover the back surface 12 of the wafer 10 at a temperature ranged between 150° C. and 175° C. under a predetermined pressure. Next, as shown in FIG. 6, after the encapsulation layer 21 is formed on the back surface of the wafer 10 and the mold surface 32 is removed, the encapsulation layer 21 has flat surface 22 opposing the surface connecting the back surface 12 of the wafer 10. Accordingly, it is unnecessary to further perform a grinding process to smooth the encapsulation layer so as to simplify the manufacturing flow.

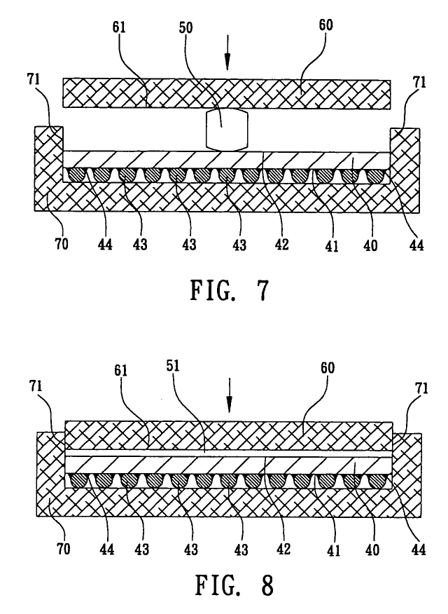

To be noted, above-mentioned process can be also applied to a wafer level package having bumps 43 encompassed by a passivation layer 44 or a protection layer, generally named as polymer collars, as shown in FIGS. 7 and 8.

Although the invention has been described in considerable detail with reference to certain preferred embodiments, it will be appreciated and understood that various changes and modifications may be made without departing from the spirit and scope of the invention as defined in the appended claims.

1. A manufacturing method of forming an encapsulation layer on a back surface of a wafer, the method comprising the steps of:
providing the wafer having the back surface and an active surface opposing to the back surface;
providing an encapsulation disposed over the back surface of the wafer;
providing a mold having a mold surface disposed over the encapsulation; and
heating the mold and moving the mold surface to press the encapsulation simultaneously so as to have the encapsulation distributed over the back surface of the wafer to form the encapsulation layer on the back surface of the wafer.

2. The method of claim 1, wherein the mold is heated at a temperature ranged between about 150° C. and about 175° C. in the step of heating the mold.

3. The method of claim 1, wherein there are a plurality of bumps formed on the active surface of the wafer.

4. The method of claim 3, wherein there is a protection layer formed on the active surface of the wafer and encompassing the bumps.

5. The method of claim 1, wherein before the step of providing the wafer, there is a wafer thinning process performed on the back surface of the wafer.

6. The method of claim 1, wherein the encapsulation is a thermosetting compound.

7. A wafer level package, comprising:
a wafer having an active surface and a back surface;
a plurality of bumps formed on the active surface of the wafer; and
an encapsulation layer formed on the back surface of the wafer by pressing and heating a thermosetting compound located over the back surface of the wafer.

8. The wafer level package of claim 7, wherein the bumps are formed on the active surface of the wafer.

9. The wafer level package of claim 7, wherein the encapsulation layer entirely covers the back surface of the wafer.

10. The wafer level package of claim 7, wherein the encapsulation layer has a flat surface opposing a surface connecting the back surface of the wafer.
